(19) United States
(12) Patent Application Publication
(10) Pub. No.: US 2008/0216302 A1
(43) Pub. Date: Sep. 11, 2008

(54) METHODS UTILIZING ORGANOSILICON COMPOUNDS FOR MANUFACTURING PRE-SEASONED COMPONENTS AND PLASMA REACTION APPARATUSES HAVING PRE-SEASONED COMPONENTS

(75) Inventors: David CHEUNG, Foster City, CA (US); Anirban GUHA, Milpitas, CA (US)

Correspondence Address: INGRASSIA FISHER & LORENZ, P.C., 7010 E. COCHISE ROAD, SCOTTSDALE, AZ, 85253, US

(73) Assignee: NOVELLUS SYSTEMS, INC., San Jose, CA (US)

(21) Appl. No.: 11/868,780

(22) Filed: Oct. 8, 2007

Related U.S. Application Data
(63) Continuation-in-part of application No. 11/683,124, filed on Mar. 7, 2007.

(51) Int. Cl. B23P 19/04; H01L 21/311

(52) U.S. Cl. 29/458; 427/299; 427/331; 427/421.1; 427/428.01; 427/429; 427/430.1

(57) ABSTRACT

Methods for pre-seasoning a component of a plasma reaction apparatus and method for fabricating plasma reaction apparatuses are provided. In an embodiment, a method for seasoning a component of a plasma reaction apparatus comprises providing an organosilicon compound, applying the organosilicon compound to the component, removing carbon atoms from the organosilicon compound, and forming a continuous, substantially uniform protective layer on the component, wherein the protective layer comprises silicon from the organosilicon compound.

### CROSS-REFERENCES TO RELATED APPLICATIONS

This is a continuation-in-part of application Ser. No. 11/683,124, filed Mar. 2, 2007, which is incorporated in its entirety herein by reference.

### FIELD OF THE INVENTION

The present technology relates generally to methods for fabricating apparatuses used in the fabrication of semiconductor devices, and more particularly, the present technology relates to methods utilizing organosilicon compounds for manufacturing pre-seasoned components and plasma reaction apparatuses having pre-seasoned components.

### BACKGROUND OF THE INVENTION

In semiconductor manufacturing, plasma ashing is the process of removing a photoresist from an etched semiconductor wafer. Plasma in this context is a gaseous mixture of ionized and excited state neutral atoms and molecules. A plasma producing apparatus, also referred to as a plasma reaction apparatus, produces a monatomic reactive species of oxygen or another gas required for the ashing process. Oxygen in its monatomic or single atom form, as O* free radicals rather than O₂, is the most common reactive species, although excited state and ionized forms of O₂ and O₃ also would be present in the plasma. The reactive species combines with the photoresist to form volatile oxides of carbon (e.g. CO, CO₂) and water, which are removed from the work piece with a vacuum pump. When used for photoresist removal, the plasma reaction apparatus often is referred to as an ashing apparatus.

The plasma reaction apparatus can be either a remote (down-stream) or an in-situ plasma reaction apparatus. FIG. 1 is a simplified cross-sectional illustration of a conventional apparatus 100 used for remote plasma exposure. In apparatus 100, a plasma 104 is created by direct excitation of molecular gas, indicated by arrows 102, flowing through a plasma generation container 106, typically a quartz tube, with an inductive coil 108 encircling it. RF power is applied to the coil 108 creating atomic, ionized, and excited state gas species or plasma. The plasma production is confined to the quartz tube. A substrate 112, such as a semiconductor substrate, upon which is disposed a photoresist is positioned in a processing chamber 114 downstream from the center of the coil 108 such that the substrate 112 is not exposed directly to the plasma. The processing chamber 114 may be separated from the quartz tube by a gas distribution plate 116, otherwise known as a showerhead, which is configured to distribute the plasma evenly over substrate 112. The processing chamber 114 includes a substrate support pedestal 120 that includes a heater (not shown) and low pressure is maintained within the processing chamber by a vacuum pump via conduit 118.

The showerhead 116, a conventional embodiment of which is illustrated in FIG. 2, typically is made from aluminum or ceramic, although other materials also have been used. As the power level and current through the coil 108 are increased, significant voltages exist on the coil. The high voltages generate a high electric field across the quartz and can cause significant ion bombardment and sputtering on the inside of the quartz tube, releasing silicon oxide (SiₓO_{y}). As the silicon oxide is sputtered from the quartz tube walls, it travels to the showerhead (carried by gravity and gas flow) and over time forms a silicon oxide coating on an underside surface 130 surface of the showerhead. As oxygen radicals pass through a new showerhead and into the processing chamber 114, the underside surface 130 of the showerhead that first contacts the plasma becomes a surface for recombination of the oxygen radicals. Recombination of the oxygen radicals on the showerhead results in an initial low ashing rate of the photoresist until the showerhead becomes “seasoned” or “conditioned”, that is, until a sufficient amount of silicon oxide has deposited and/or aluminum oxide has formed on the showerhead so that the recombination rate is reduced to that expected for a silicon oxide surface. Thus, as the showerhead becomes seasoned, the ashing rate increases. Once the showerhead is sufficiently seasoned, the ashing rate becomes substantially uniform.

To make the ashing rate uniform when a new showerhead is installed in the plasma reaction apparatus, efforts to season the showerhead in situ have been made. These efforts include subjecting the new showerhead to the plasma process, with or without semiconductor wafers in the processing chamber, until the showerhead is seasoned. This seasoning or conditioning process typically requires 10 to 25 hours or more of plasma generation in the plasma reaction apparatus, which can be quite costly. If semiconductor wafers are not in the processing chamber during seasoning, this seasoning process results in downtime of the apparatus. If semiconductor wafers are in the chamber during seasoning, the wafers may experience low ash rate and poor ash uniformity wherein the photoresists of the wafers may not be ashed sufficiently or uniformly and may have to be subjected to the plasma for a longer period of time to be removed.

Accordingly, it is desirable to provide methods for pre-seasoning showerheads and other components of a plasma reaction apparatus before installation in plasma reaction apparatus. It also is desirable to provide methods for pre-seasoning showerheads and other components of a plasma reaction apparatus that are cost-efficient. In addition, it is desirable to provide methods for fabricating plasma reaction apparatus with pre-seasoned showerheads and components. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

A method for seasoning a component of a plasma reaction apparatus is provided in accordance with an exemplary embodiment of the present invention. The method comprises providing an organosilicon compound, applying the organosilicon compound to the component, and removing carbon atoms from the organosilicon compound. A continuous, substantially uniform protective layer is formed on the component. The protective layer comprises silicon from the organosilicon compound.

A method for fabricating a plasma reaction apparatus is provided in accordance with an exemplary embodiment of the present invention. The method comprises providing an aluminum component of the plasma reaction apparatus and applying an organosilicon compound to the component. Carbon atoms are at least substantially removed from the organosilicon compound and a protective layer is formed on the component, the protective layer having a predetermined thickness. The component is installed into the plasma reaction apparatus.

### BRIEF DESCRIPTION OF THE DRAWINGS

The present invention will hereinafter be described in conjunction with the following drawing figures, wherein like numerals denote like elements, and wherein:

FIG. 1 is a cross-sectional view of a conventional plasma reaction apparatus;

FIG. 2 is an isometric view of a showerhead of the plasma reaction apparatus of FIG. 1;

FIG. 3 is a method for fabricating a plasma reaction apparatus in accordance with an exemplary embodiment of the present invention;

FIG. 4 is a method for pre-seasoning a component of a plasma reaction apparatus in accordance with an exemplary embodiment of the present invention; and

FIG. 5 is a cross-sectional view of a showerhead of a plasma reaction apparatus wherein the showerhead has a protective layer in accordance with an exemplary embodiment of the present invention.

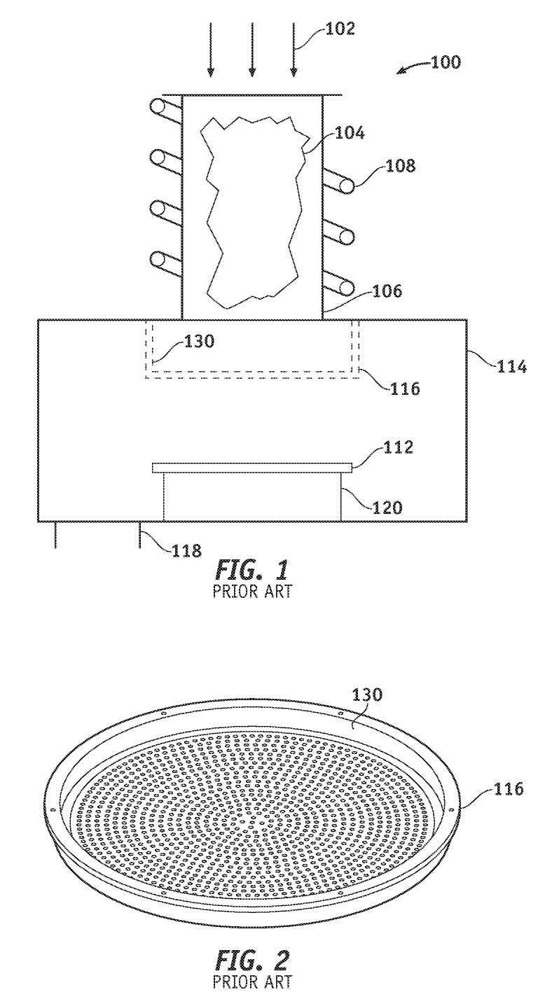

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

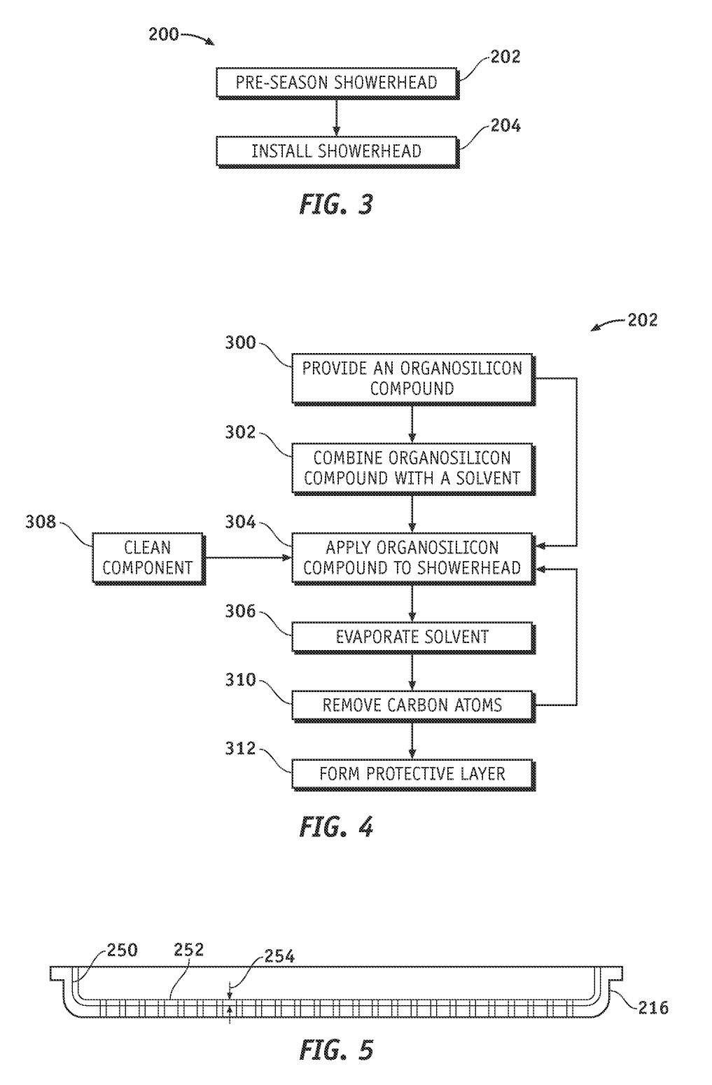

A method 200 for fabricating a plasma reaction apparatus, in accordance with an exemplary embodiment of the present invention, is illustrated in FIG. 3. The method begins with the step of pre-seasoning a gas distribution plate, referred to herein as a “showerhead” (step 202). While the various embodiments of the method for fabricating a plasma reaction apparatus will be discussed, for illustration purposes, in terms of pre-seasoning a showerhead of the apparatus, it will be appreciated that the various embodiments are not limited to pre-seasoning of showerheads but can be used to pre-season any desired component of the apparatus. The showerhead or other component(s) can comprise a ceramic but preferably comprise a metal, and more preferably comprise aluminum.

As used herein, the term “pre-seasoning” means coating a surface of the showerhead with a continuous, substantially uniform protective layer before installation of the showerhead in a plasma reaction apparatus. The protective layer is a material layer formed on the underside surface(s) of the showerhead, that is, the surface(s) of the showerhead facing the plasma generation container (i.e. quartz tube) when installed in a plasma reaction apparatus, although the protective layer can be formed any other surface of the showerhead. The protective layer is any material layer that, during ashing, minimizes or prevents the recombination of oxygen from the oxygen-based plasma onto the showerhead and minimizes or prevents the deposition of silicon oxide resulting from sputtering of the plasma generation container during plasma generation. In one exemplary embodiment, the protective layer comprises silicon oxide (SiₓO_{y}). Once the showerhead is pre-seasoned, it is installed in the plasma reaction apparatus (step 204). Accordingly, a new pre-seasoned showerhead may be installed into a new plasma reaction apparatus or can replace a used showerhead in a plasma reaction apparatus. In either case, use of a pre-seasoned showerhead in a plasma reaction apparatus results in an improved initial ashing rate that stays substantially uniform during the ashing process on multiple wafers, thus reducing incomplete ashing of the photoresist.

A more detailed description of the method (step 202) for pre-seasoning a showerhead is illustrated in FIG. 4. The method includes the step of providing an organosilicon compound (step 300). The organosilicon compound can be any compound comprising carbon atoms and silicon atoms, which readily bond to aluminum. In one exemplary embodiment, the organosilicon compound further comprises oxygen atoms, although, as described in more detail below, oxygen atoms can be provided after the organosilicon compound is applied to the showerhead to produce silicon oxide. Examples of suitable organosilicon compounds include tetraethoxysilane (TEOS), tetramethoxysilane, tetramethyl silicon, methyl silsesquioxane (MSQ), siloxanes, and the like, and combinations thereof. An exemplary siloxanes include methylsiloxanes, such as ACCUGLASS® 512B, available from Honeywell Electronic Materials of Sunnyvale, Calif.

In one exemplary embodiment of the invention, the organosilicon compound is combined with an organic solvent (step 302) to form a dilution that can be applied easily and uniformly to the showerhead. The organic solvent that is combined with the organosilicon compound depends on various factors such as the type of organosilicon compound to be applied to the showerhead, the desired viscosity of the dilution, the temperature at which the solvent evaporates, the cost of the solvent, and the like. Contemplated solvents are those which are easily removed within the context of the applications disclosed herein. For example, in one exemplary embodiment, the solvents comprise relatively low boiling points as compared to the boiling points of the organosilicon compound. In some embodiments, contemplated solvents have a boiling point of less than about 250° C. In other embodiments, contemplated solvents have a boiling point in the range of from about 50° C. to about 250° C. to allow the solvent to evaporate from the applied coating and leave the active organosilicon compound in place. In other contemplated embodiments, the solvent may comprise hydrocarbons, ketones, alcohols, esters, ethers, amides, amines, or combinations thereof. Examples of suitable organic solvents include isopropyl alcohol (IPA), acetone, diethylketone, methylethylketone, or combinations thereof. The concentration of the organosilicon compound in the organic solvent ranges from greater than zero percent by volume to less than or equal to 100%. In other words, the organosilicon compound can be used in a significantly diluted form, in a diluted form, or in at least a substantially pure form. In one exemplary embodiment, the dilution can comprise approximately 15% TEOS in IPA.

In another exemplary embodiment of the invention, the method (step 202) further comprises cleaning the showerhead (step 308). Any suitable method for cleaning the showerhead of oils, greases and other organic and inorganic contamination may be used. In an exemplary embodiment of the invention, cleaning of the showerhead may comprise cleaning all surfaces of the showerhead with electronic grade isopropanol (IPA). If the showerhead is extremely oily or has many blind holes or areas, the showerhead also may be washed with a suitable cleaning compound, such as Labtone® cleaning compound available from VWR International, Inc. of Chester, Pa. The showerhead can be rinsed in water and may be further cleaned in an acid bath such as, for example, a nitric acid bath containing 50% nitric acid and 50% water. Once suitably cleaned, the showerhead then may be rinsed and dried.

The method continues in accordance with an exemplary embodiment of the present invention with the application of the organosilicon compound, with or without the organic solvent, to the showerhead (step 304). The organosilicon compound can be applied to the showerhead using any suitable method, such as by brushing, rolling, or spraying the organosilicon compound onto the surfaces of the showerhead to be coated, by dip coating the showerhead in the organosilicon compound, or by any other method or combination of methods that permits the organosilicon compound to be applied uniformly or substantially uniformly to the surface(s) of the showerhead.

After the application of the organosilicon compound to the showerhead, the organic solvent, if present, is evaporated (step 306). In this regard, the solvent may be permitted to evaporate at room temperature (about 16° C. to about 28° C.) or may be heated to the boiling point of the solvent for a sufficient time to permit the solvent to at least substantially evaporate. The temperature of the solvent is maintained below the boiling point of the organosilicon compound to prevent evaporation thereof. The solvent can be heated using any known process such as, for example, placing the showerhead on a heating plate or disposing the showerhead in an oven.

During or after evaporation of the solvent, at least substantially all of the carbon atoms are removed from the organosilicon compound (step 310) to obtain a silicon oxide protective layer on the showerhead. The carbon atoms can be removed from the organosilicon compound using any method that is suitable depending on the chemical properties of the organosilicon compound. In one exemplary embodiment, the carbon atoms can be removed by subjecting the organosilicon compound to an oxygen plasma or otherwise to atomic oxygen, which in turn results in a substantially uniform protective layer comprising silicon dioxide (SiO₂) on the surface of the showerhead. In another exemplary embodiment, the carbon atoms are removed by subjecting the organosilicon compound to thermal oxidation, that is, heating the organosilicon compound in the presence of an oxygen ambient. If, as described above, the organosilicon compound that does not originally comprise oxygen, exposure to atomic oxygen will further result in oxidation of the organosilicon compound, thus forming a substantially uniform protective layer comprising silicon dioxide (SiO₂) on the surface of the showerhead.

Once the substantially uniform protective layer is formed on the showerhead, the steps 304, 306, and 308 can be repeated in any number of cycles to form a final continuous, substantially uniform protective layer having a desired thickness (step 312). Referring momentarily to FIG. 5, a continuous, substantially uniform protective layer 252 is formed, for example, on an underside surface 250 of a showerhead 216. As used herein, the “underside surface 250” of showerhead 216 is the surface (or surfaces) of the showerhead that is facing or exposed to the plasma generation container when installed in an plasma reaction apparatus (i.e., ashing apparatus). In an exemplary embodiment of the invention, the final protective layer 252 has a thickness, indicated by arrows 254, in the range of about 0.001 μm to about 50 μm. In a preferred embodiment of the invention, the final protective layer 252 has a thickness 254 in the range of about 0.01 μm to about 5 μm. In a more preferred embodiment, the final protective layer 252 has a thickness 254 of about 1 μm.

### EXAMPLE

The following is provided as an exemplary embodiment of a method for pre-seasoning a component of a plasma reaction apparatus and is not meant to limit the invention in any way. In accordance with the embodiment, a showerhead for a Gamma XPR photoresist removal system was precleaned by wiping the surfaces of the showerhead with IPA. The showerhead was placed on a heating plate with its underside surface exposed. The heating plate was maintained at a temperature of about 100° C. A 15% TEOS dilution in IPA was prepared and the dilution was poured into a conventional spray bottle. The solution was misted onto the underside surface of the showerhead forming a continuous, uniform layer of solution on the showerhead surface. The IPA was permitted to evaporate. The showerhead was turned over and the opposing surface of the showerhead was misted with the solution to form a continuous, uniform layer of the solution. Again, the IPA was allowed to evaporate. The process of spraying the solution onto the opposing surfaces of the showerhead and permitting the IPA to evaporate after each spray was repeated five times.

The showerhead then was installed in a Gamma XPR apparatus. A pressure of about 1.2 Torr was created within the apparatus, which was heated to a temperature of about 150-280° C. A plasma of O₂ and N₂ was created and caused to flow over the showerhead at an overall flow rate of about 2 liters per minute for approximately 30 minutes, forming a layer of silicon oxide on the surfaces of the showerhead.

Accordingly, methods for pre-seasoning a showerhead or other components before installation into a plasma reaction apparatus (i.e., ashing apparatus) have been provided. Methods for fabricating a plasma reaction apparatus also have been provided. Use of a pre-seasoned showerhead or other components in a plasma reaction chamber results in an improved initial ashing rate that stays substantially uniform during the ashing process over multiple wafers, thus minimizing or preventing first wafer effects. By applying to the showerhead or other components an organosilicon compound as described above, cost-efficient and time-effective methods for pre-seasoning the showerhead or other components can be achieved. While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A method for seasoning a component of a plasma reaction apparatus, the method comprising the steps of:
providing an organosilicon compound;
applying the organosilicon compound to the component;
removing carbon atoms from the organosilicon compound; and
forming a continuous, substantially uniform protective layer on the component, wherein the protective layer comprises silicon from the organosilicon compound.

2. The method of claim 1, wherein the step of providing an organosilicon compound comprises the step of providing an organosilicon compound comprising oxygen atoms.

3. The method of claim 1, wherein the step of providing an organosilicon compound comprises the step of providing tetraethoxysilane (TEOS), tetramethoxysilane, tetramethyl silicon, a siloxane, methyl silsesquioxane (MSQ), or combinations thereof.

4. The method of claim 1, further comprising the steps of:
combining an organic solvent with the organosilicon compound to form a dilution, wherein the step of combining is performed before the step of applying and wherein the step of applying comprises applying the dilution; and
at least substantially evaporating the organic solvent from the component, the step of at least substantially evaporating performed after the step of applying.

5. The method of claim 4, wherein the step of at least substantially evaporating the organic solvent comprises the step of heating the organic solvent.

6. The method of claim 4, wherein the step of removing is performed during the step of at least substantially evaporating.

7. The method of claim 4, wherein the step of combining an organic solvent with the organosilicon compound comprises the step of combining with the organosilicon compound an organic solvent having a boiling point that is less than a boiling point of the organosilicon compound.

8. The method of claim 4, wherein the step of combining an organic solvent with the organosilicon compound comprises the step of combining with the organosilicon compound a hydrocarbon, a ketone, an alcohol, an ester, an ether, an amide, an amine, or a combination thereof.

9. The method of claim 1, wherein the step of applying comprises brushing, rolling, or spraying the organosilicon compound onto the component, or dip coating the component into the organosilicon compound.

10. The method of claim 1 further comprising, before the step of applying, the step of cleaning the component.

11. The method of claim 1, wherein the step of removing carbon atoms comprises removing carbon atoms by heating the organosilicon compound in the presence of oxygen.

12. The method of claim 1, wherein the step of removing carbon atoms comprises removing carbon atoms by exposing the organosilicon compound to atomic oxygen.

13. The method of claim 1, wherein the steps of removing and forming are performed substantially simultaneously.

14. The method of claim 1, wherein the steps of applying and removing can be repeated until the protective layer of a desired thickness is formed.

15. The method of claim 1, wherein the step of forming a continuous, substantially uniform protective layer on the component comprises forming the protective layer having a thickness in the range of about 0.001 μm to about 50 μm.

16. The method of claim 1, wherein the step of forming a continuous, substantially uniform protective layer on the component comprises forming the protective layer having a thickness in the range of about 0.01 μm to about 5 μm.

17. A method for fabricating a plasma reaction apparatus, the method comprising the steps of:
providing an aluminum component of the plasma reaction apparatus;
applying an organosilicon compound to the component;
at least substantially removing carbon atoms from the organosilicon compound;
forming a protective layer on the component, the protective layer having a predetermined thickness; and
installing the component into the plasma reaction apparatus.

18. The method of claim 17, wherein the step of applying an organosilicon compound comprises the step of providing an organosilicon compound comprising oxygen atoms.

19. The method of claim 17, wherein the step of applying an organosilicon compound comprises the step of applying tetraethoxysilane (TEOS), tetramethoxysilane, tetramethyl silicon, a siloxane, methyl silsesquioxane (MSQ), or combinations thereof.

20. The method of claim 17, further comprising the steps of:
combining an organic solvent with the organosilicon compound to form a dilution, wherein the step of combining is performed before the step of applying and wherein the step of applying comprises applying the dilution; and
at least substantially evaporating the organic solvent from the component, the step of at least substantially evaporating performed after the step of applying.

21. The method of claim 20, wherein the step of at least substantially evaporating the organic solvent comprises the step of heating the organic solvent.

22. The method of claim 20, wherein the step of removing is performed during the step of at least substantially evaporating.

23. The method of claim 20, wherein the step of combining an organic solvent with the organosilicon compound comprises the step of combining with the organosilicon compound an organic solvent having a boiling point that is less than a boiling point of the organosilicon compound.

24. The method of claim 20, wherein the step of combining an organic solvent with the organosilicon compound comprises the step of combining with the organosilicon compound a hydrocarbon, a ketone, an alcohol, an ester, an ether, an amide, an amine, or a combination thereof.

25. The method of claim 17, wherein the step of applying comprises brushing, rolling, or spraying the organosilicon compound onto the component, or dip coating the component into the organosilicon compound.

26. The method of claim 17, wherein the step of forming comprises forming a protective layer having a substantially uniform thickness in the range of about 0.001 μm to about 50 μm.

27. The method of claim 17, wherein the step of at least substantially removing carbon atoms comprises removing carbon atoms by heating the organosilicon compound in the presence of oxygen.

28. The method of claim 17, wherein the step of at least substantially removing carbon atoms comprises removing carbon atoms by exposing the organosilicon compound to atomic oxygen.

29. The method of claim 17, wherein the steps of applying and at least substantially removing are repeated to form the protective layer of the predetermined thickness.

30. The method of claim 17, wherein the step of installing is performed before the step of at least substantially removing.
